(19) United States
(12) Patent Application Publication
(10) Pub. No.: US 2010/0283143 A1
(43) Pub. Date: Nov. 11, 2010

(54) Die Exposed Chip Package

(76) Inventors: Chenglin Liu, San Jose, CA (US); Shiann-Ming Liou, Campbell, CA (US)

Correspondence Address: Sadler, Breen, Morasch & Colby, ps, 601 W. Main Ave., Suite 1300, Spokane, WA, 99201, US

(21) Appl. No.: 12/772,869

(22) Filed: May 3, 2010

Related U.S. Application Data
(60) Provisional application No. 61/176,073, filed on May 6, 2009.

(51) Int. Cl. H01L 23/34; H01L 21/50; H01L 23/48

(52) U.S. Cl. 257/713; 438/122; 257/738; 438/118; 257/E21.499; 257/E23.01; 257/E23.08

(57) ABSTRACT

This disclosure describes a chip package. In one embodiment, a semiconductor chip package includes a thermal dissipater placed on top of an integrated-circuit die, the thermal dissipater having a same or similar coefficient of thermal expansion as that of the integrated-circuit die.

### RELATED APPLICATION

This disclosure claims priority to U.S. Provisional Patent Application Ser. No. 61/176,073 filed May 6, 2009, the disclosure of which is incorporated by reference herein in its entirety.

### BACKGROUND

Conventional semiconductor chip packages are often surface mounted to a printed circuit board using a ball grid array and include a structural material over the package's integrated-circuit die. This structural material is not as thermally conductive as the die. As a result, excessive heat may build up on the die. This heat dissipates to the printed circuit board on which the ball grid array is mounted. Due to differing coefficients of thermal expansion between the die, the printed circuit board, and the structural material, each expands differently when heated. This differing expansion causes stress that may fracture solder-ball joints on the ball grid array. The solder-ball joints often serve as mechanical and electrical connections to the printed circuit board. As such, fractures cause numerous problems.

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

### SUMMARY

This summary is provided to introduce subject matter that is further described below in the Detailed Description and Drawings. Accordingly, this Summary should not be considered to describe essential features nor used to limit the scope of the claimed subject matter.

In one embodiment, a semiconductor chip package is described that comprises a surface-mounting structure having a structure top, an integrated-circuit die having a first coefficient of thermal expansion (CTE), a die top, and a die bottom, the die bottom being attached to the structure top, and a thermal dissipater attached to the die top, the thermal dissipater not acting as an integrated circuit and having a second CTE similar to the first CTE.

In another embodiment, a ball grid array (BGA) semiconductor chip package is described that comprises a ball grid array having an array bottom and an array top, the array bottom having solder-ball joints for electrically and mechanically connecting the BGA semiconductor chip package to a printed circuit board, the array top having a surface-mount contact, one of the solder-ball joints electrically connected to the surface-mount contact through a via within the ball grid array, an integrated-circuit die having a die top and a die bottom, the die bottom being attached to the array top of the ball grid array, the die top having a die contact, a wire electrically connecting the die contact to the surface-mount contact, a thermal dissipater attached to the die top, the thermal dissipater not acting as an integrated circuit and having a coefficient of thermal expansion similar to that of the integrated-circuit die, and a structural material having a different coefficient of thermal expansion than the integrated-circuit die, wherein the structural material encapsulates the integrated-circuit die, encapsulates the wire, and is in contact with at least part of the thermal dissipater.

In yet another embodiment, a method is described that comprises attaching a thermal dissipater to an integrated-circuit die, the thermal dissipater not acting as an integrated circuit and having a coefficient of thermal expansion similar to that of the integrated-circuit die and applying a structural material proximate to the thermal dissipater, the structural material capable of supporting a heat sink in thermal contact with the thermal dissipater.

### BRIEF DESCRIPTION OF THE DRAWINGS

The detailed description is described with reference to the accompanying figures. In the figures, the left-most digit of a reference number identifies the figure in which the reference number first appears. The use of the same reference numbers in different instances in the description and the figures indicate similar or identical items.

FIG. 1 illustrates a top-down view of a chip package, and a cross-section view of the chip package.

FIG. 2 illustrates a bottom-up view of a ball grid array (BGA).

FIG. 3 illustrates a cross-section view of a semiconductor chip package having an improved thermal design and a thin layer of structural material over a thermal dissipater.

FIG. 4 illustrates a top-down view of a semiconductor chip package having an improved thermal design.

FIG. 5 illustrates a top-down view of a semiconductor chip package having an improved thermal design and having a differently shaped and oriented thermal dissipater to that of FIG. 4.

FIG. 6 illustrates a method for improving the thermal design of a semiconductor chip package.

### DETAILED DESCRIPTION

As noted in the Background above, conventional ball grid array (BGA) semiconductor chip packages may fracture when heated or cooled. This disclosure describes techniques and apparatuses for improved thermal design of BGA semiconductor chip packages. The improvements described result in cooler operating temperatures and/or less stress on solder-ball joints, as well as other desirable features.

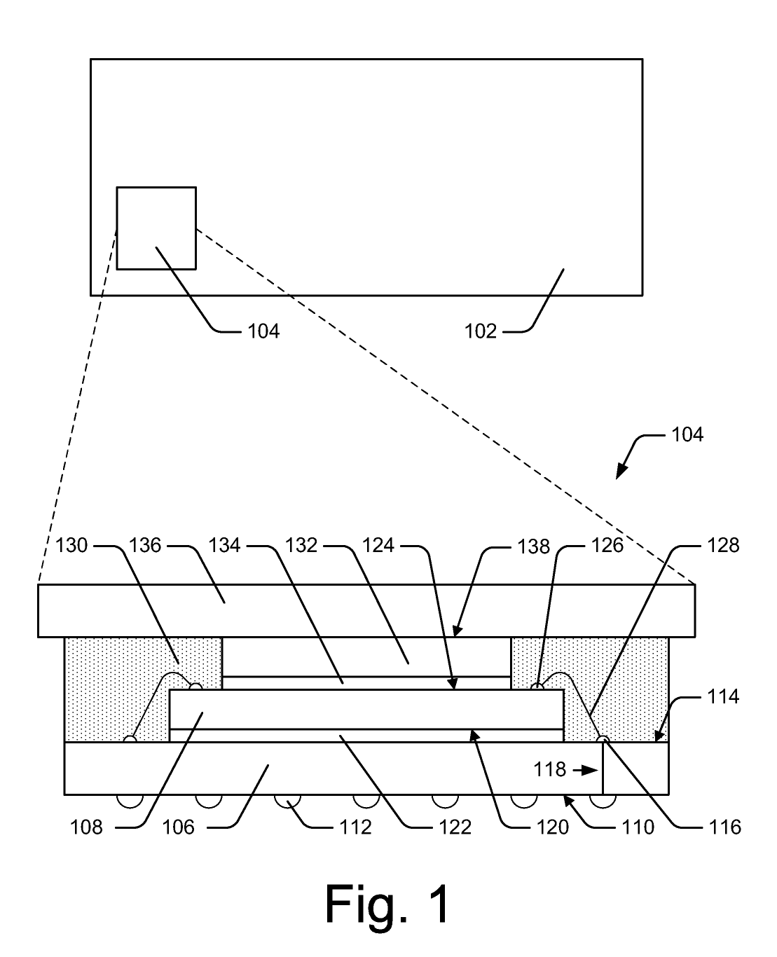

FIG. 1 illustrates a printed circuit board 102 on which one or more semiconductor chip packages 104 are surface mounted. Printed circuit board 102 may be a dual in-line memory module (DIMM) of random-access-memory (RAM), a motherboard for a computing device, or a peripheral component interconnect (PCI) board for audio or Ethernet, to name a few. Semiconductor chip package 104 includes one or more integrated circuits, such as a memory chip of RAM, a processor to be mounted on a motherboard, or an audio or Ethernet controller.

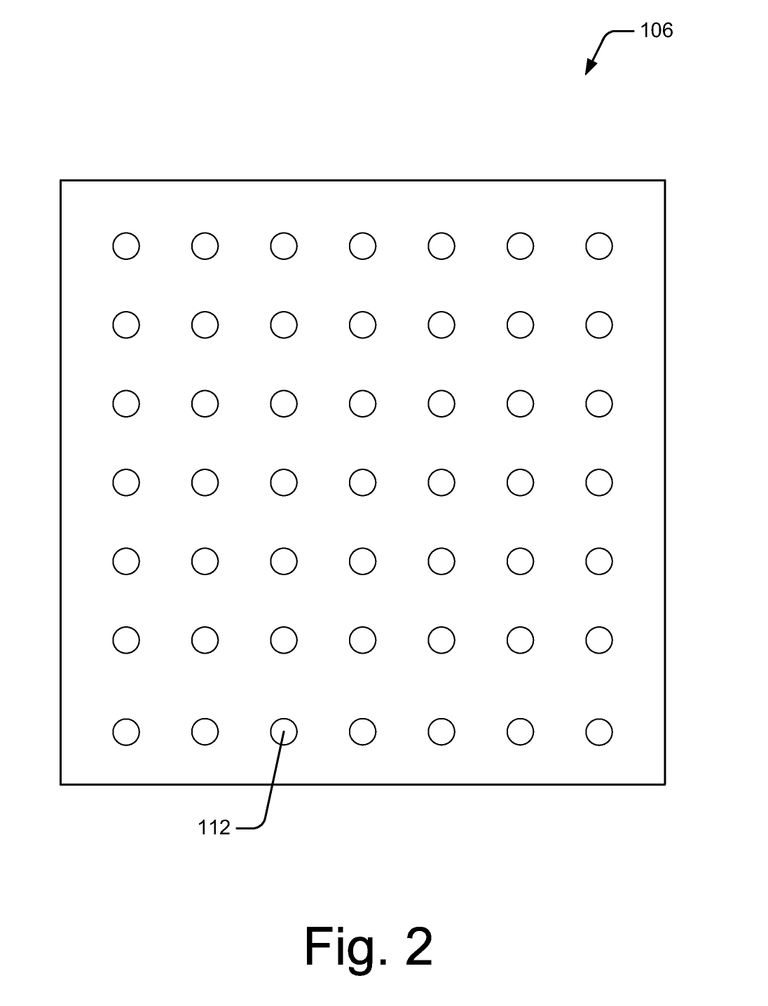

FIG. 1 also illustrates a cross-section view of semiconductor chip package 104, which is configured to improve thermal dissipation and/or reduce stress on solder-ball joints. A ball grid array 106 acts as a surface-mounting structure for mounting an integrated-circuit die 108 to printed circuit board 102. Ball grid array 106 has an array bottom 110 including one or more solder-ball joints 112. In the cross-section view of FIG. 1, seven solder-ball joints 112 are shown but other configurations are possible. For a bottom-up view of ball grid array 106 see FIG. 2. Ball grid array 106, as shown in FIG. 1, has an array top 114 including one or more surface-mount contacts 116. Surface-mount contacts 116 are shown as raised in FIG. 1 but can be embedded within the array top 114 of ball grid array 106.

Ball grid array 106 includes internal via 118, which electrically connects one of solder-ball joints 112 with a surface-mount contact 116, though a one-to-one electrical connection is not required. Two or more solder-ball joints 112 can be electrically connected to a single surface-mount contact 116 or a single solder-ball joint 112 can be electrically connected to two or more surface-mount contacts 116. Some solder-ball joints 112 exist solely for mechanical stability of the chip package and therefore are not electrically connected to surface-mount contact 116.

Integrated-circuit die 108 includes internal circuitry that, when properly connected to the printed circuit board (not shown in cross section), serves as part of a functional circuit. While only one integrated-circuit die 108 is shown, multiple dies can be used. Integrated-circuit die 108 has a die bottom 120, which is attached to array top 114 of ball grid array 106 using an adhesive film 122. Adhesive film 122 is thermally conductive and/or electrically insulating. Integrated-circuit die 108 has a die top 124, including one or more die contacts 126. Die contacts 126 serve as electrical connections to the internal circuitry within integrated-circuit die 108. Die contacts 126 are shown as raised in FIG. 1 but can be embedded within die top 124 of integrated-circuit die 108.

One or more wires 128 electrically connect die contacts 126 with surface-mount contacts 116. In this way, wires 128 serve as the electrical connections between integrated-circuit die 108 and ball grid array 106. As shown, one wire 128 electrically connects one surface-mount contact 116 with one die contact 126, though other arrangements are contemplated.

A structural material 130 (shaded) encapsulates exposed areas of integrated-circuit die 108, surface-mount contacts 116, die contacts 126, and wires 128. Structural material 130 is in contact with at least part of thermal dissipater 132. Structural material 130 provides mechanical support and stability to chip package 104. In this embodiment, structural material 130 is a plastic with a coefficient of thermal expansion that is different from that of integrated-circuit die 108. Therefore, when heated, structural material 130 expands at a different rate than integrated-circuit die 108. Structural material 130 does not dissipate (or absorb) heat as well as thermal dissipater 132 because structural material 130 has a lower thermal conductance than thermal dissipater 132.

Thermal dissipater 132 is attached to die top 124 of integrated-circuit die 108 using an adhesive film 134. Adhesive film 134 can be thermally conductive and/or electrically insulating if desired. Thermal dissipater 132 has a similar, if not identical, coefficient of thermal expansion compared to that of integrated-circuit die 108. If different, the difference between thermal dissipater 132's coefficient of thermal expansion and integrated-circuit die 108's coefficient of thermal expansion is less than the difference between structural material 130's coefficient of thermal expansion and integrated-circuit die 108's coefficient of thermal expansion. Thermal dissipater 132 has greater thermal conductivity than structural material 130. This greater thermal conductivity enables heat to effectively dissipate from integrated-circuit die 108 to heat sink 136, resulting in reduced operating temperatures. Further, if chip package 104 gets warm, thermal dissipater 132 expands at a similar or same rate as integrated-circuit die 108, thereby producing less stress on various elements of semiconductor chip package 104 (e.g., on solder-ball joints 112).

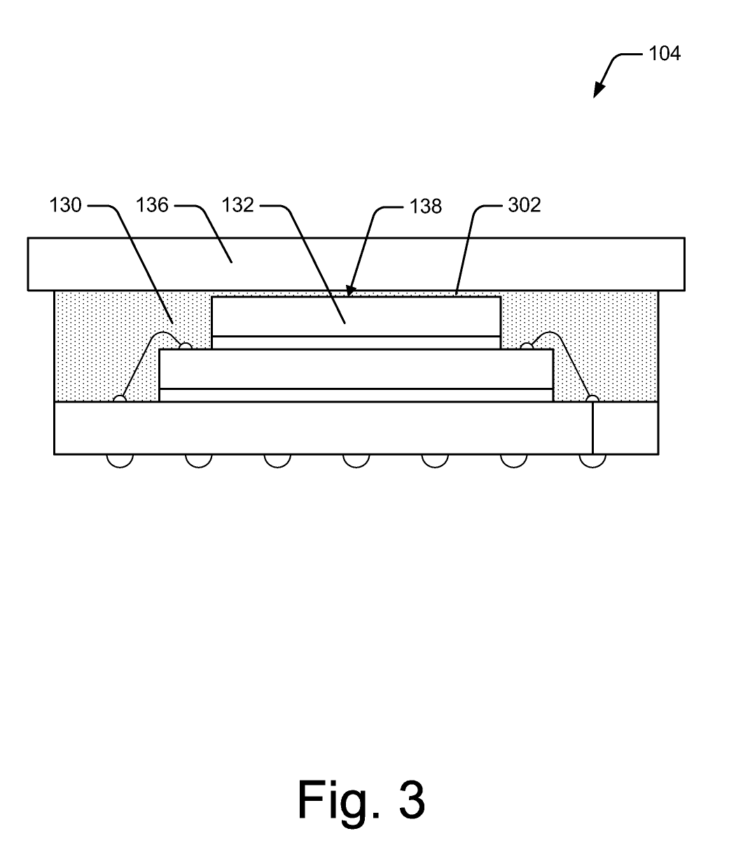

Heat sink 136 resides on a dissipater top 138 of thermal dissipater 132 in FIG. 1, but in the embodiment shown in FIG. 3, a thin layer 302 of structural material 130 may be present between heat sink 136 and thermal dissipater 132. This thin layer 302 of structural material 130 is thin enough to still allow for improved thermal dissipation to heat sink 136 while at the same time provide mechanical support for chip package 104.

In other embodiments heat sink 136 is not present. Without heat sink 136, thermal dissipater 132 maintains the benefit of reduced stress as temperatures change. Also, thermal dissipater 132 dissipates heat from integrated-circuit die 108.

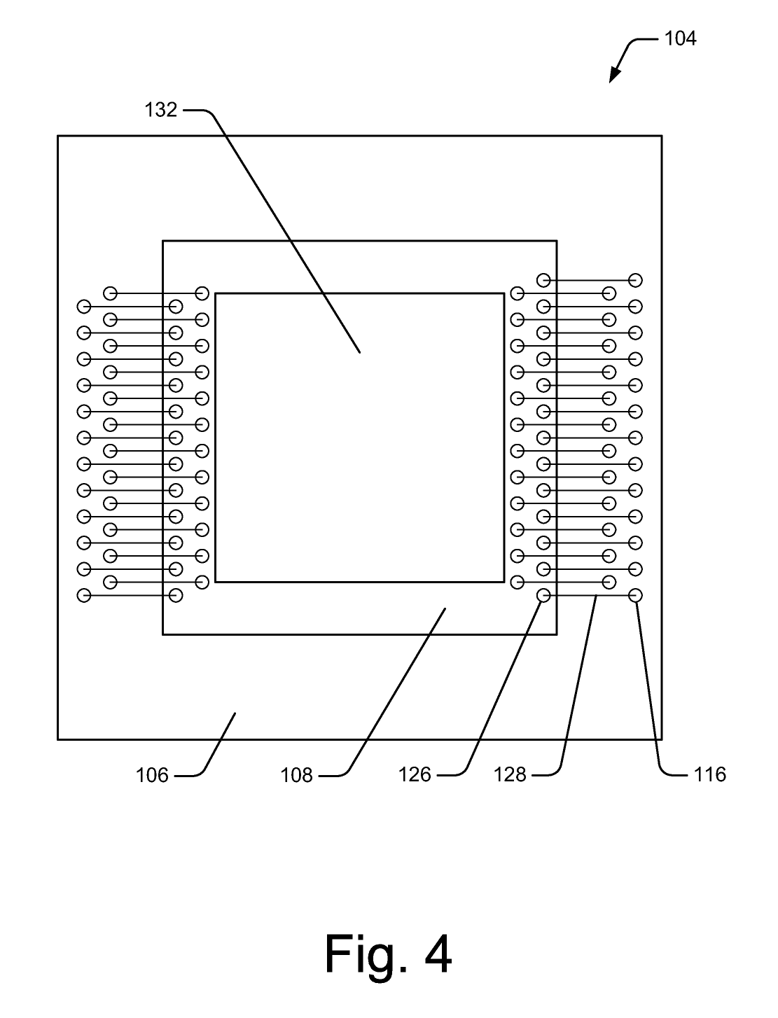

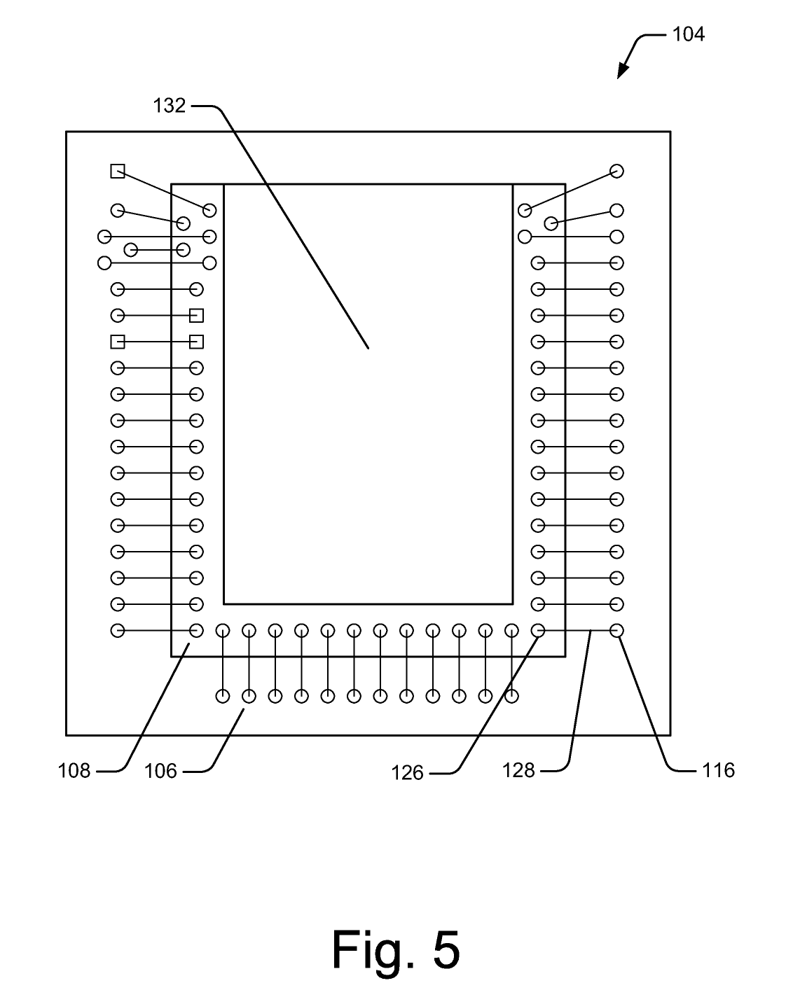

To further illustrate the layout of chip package 104, consider the top-down view of FIG. 4. FIG. 4 does not include structural material 130 or heat sink 136 as they would obscure the other elements. Here thermal dissipater 132 is square shaped and is approximately centered over the middle of integrated-circuit die 108. Note that while particular shapes of the elements are illustrated in FIG. 4, various shapes of ball grid array 106, integrated-circuit die 108, thermal dissipater 132, and contacts (116 and 126) are contemplated. For example, FIG. 5 illustrates a top-down view of an alternate embodiment of chip package 104. Thermal dissipater 132 is rectangular in this embodiment and one of thermal dissipater 132's edges is flush with one of integrated-circuit die 108's edges.

Due to the improved thermal design made possible by placement of thermal dissipater 132, chip packages mounted using a ball grid array may be used in high-power implementations. For example, random-access-memory chips, gigabit Ethernet controllers, and even high-powered processors may now be mounted using a ball grid array and thermal dissipater 132.

Note that one or more of the entities shown in FIGS. 1-5 may be further divided, combined, and so on. Thus, these entities illustrate some of many possibilities (alone or combined) for improved thermal performance.

Method for Improving Chip Package Design

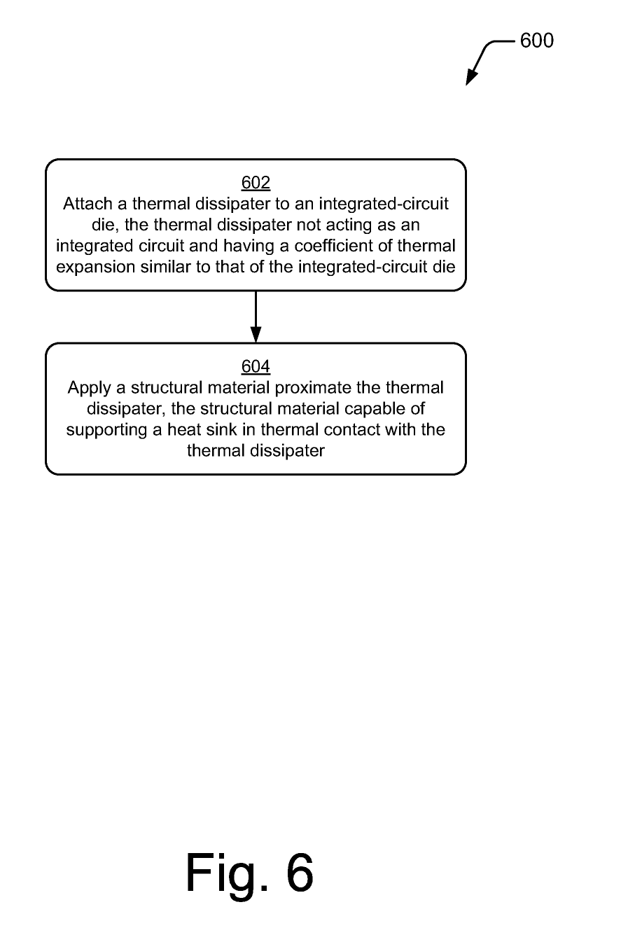

FIG. 6 illustrates a method 600 for improving a thermal design of a chip package. At 602, a thermal dissipater is attached to an integrated-circuit die. The thermal dissipater does not act as an integrated circuit itself but may be of the same material as the integrated-circuit die. The thermal dissipater has a coefficient of thermal expansion similar to or identical to that of the integrated-circuit die.

At 604, a structural material is applied proximate the thermal dissipater. The structural material provides mechanical support for the chip package. The structural material is capable of supporting a heat sink and allowing the heat sink to be in thermal contact with the thermal dissipater. Thermal contact means that the structural material allows transfer of heat from the thermal dissipater to the heat sink.

By way of example, consider application of method 600 to help produce chip package 104 as illustrated in FIG. 1. At 602, thermal dissipater 132 is attached to integrated-circuit die 108. At 604, structural material 130 is applied proximate thermal dissipater 132. Multiple techniques may be used to accomplish this. It is efficient, from a manufacturing standpoint, to use a mold specifically designed to produce chip package 104. The mold is either designed so that structural material 130 leaves the dissipater top 138 of thermal dissipater 132 exposed as in FIG. 1 or covers thermal dissipater 132 with a thin layer 302 as in FIG. 3. A liquid form of structural material 130 is poured (e.g., sprayed, injected, etc.) into the mold. Structural material 130 is then hardened and chip package 104 is complete (if no heat sink 136 is to be added). Chip package 104 can then be mounted on printed circuit board 102.

Using a specific mold may be cost prohibitive for lower-volume builds. In this case, a generic mold can be used. The generic mold leaves a thick layer of structural material over the dissipater top 138 of thermal dissipater 132. This allows for the generic mold to be used with chip packages of varying heights without needing to be retooled. A liquid form of structural material 130 is poured into the generic mold. Structural material 130 is then hardened. A top layer of structural material 130 can then be removed until the chip package of FIG. 1 or FIG. 3 is produced. The top layer may be removed by grinding off structural material 130 or by burning off structural material 130 using laser ablation.

Although the subject matter has been described in language specific to structural features and/or methodological techniques and/or acts, it is to be understood that the subject matter defined in the appended claims is not necessarily limited to the specific features, techniques, or acts described above, including orders in which they are performed. For example, while the embodiments above are described in the context of ball grid array surface-mount packaging, the techniques described may be applied to other surface-mount packaging types (e.g., pin-grid array, lead frame, etc.). Those surface-mount packaging types may not have solder-ball joints that fracture but may benefit from the improved thermal dissipation described herein.

What is claimed is:

1. A semiconductor chip package comprising:
a surface-mounting structure having a structure top;
an integrated-circuit die having (i) a first coefficient of thermal expansion, (ii) a die top, and (iii) a die bottom, the die bottom being attached to the structure top; and
a thermal dissipater attached to the die top, the thermal dissipater (i) not acting as an integrated circuit and (ii) having a second coefficient of thermal expansion similar to the first coefficient of thermal expansion.

2. The semiconductor chip package as recited in claim 1, further comprising:
a structural material (i) providing mechanical stability to the semiconductor chip package and (ii) having a third coefficient of thermal expansion, the difference between the third coefficient of thermal expansion and the first coefficient of thermal expansion being greater than the difference between the second coefficient of thermal expansion and the first coefficient of thermal expansion,
wherein the structural material
encapsulates the integrated-circuit die, and
is in contact with at least part of the thermal dissipater.

3. The semiconductor chip package as recited in claim 2, wherein:
the thermal dissipater has a dissipater top; and
the semiconductor chip package further comprises
a heat sink placed on the dissipater top, and
a thin layer of the structural material between (i) the dissipater top and (ii) the heat sink.

4. The semiconductor chip package as recited in claim 2, wherein:
the structure top includes a surface-mount contact;
the die top includes a die contact; and
the semiconductor chip package further comprises a wire electrically connecting the die contact to the surface-mount contact,
wherein the structural material encapsulates (i) the wire, (ii) the surface-mount contact, and (iii) the die contact.

5. The semiconductor chip package as recited in claim 4, wherein the surface-mounting structure is a ball grid array having a structure bottom, the structure bottom having a solder-ball joint for electrically and mechanically connecting the semiconductor chip package to a printed circuit board, the solder-ball joint being electrically connected to the surface-mount contact through a via within the ball grid array.

6. The semiconductor chip package as recited in claim 2, wherein:
the thermal dissipater has a first thermal conductance; and
the structural material has a second thermal conductance that is less than the first thermal conductance.

7. The semiconductor chip package as recited in claim 1, wherein:
the second coefficient of thermal expansion is identical to the first coefficient of thermal expansion;
the integrated-circuit die comprises a first material; and
the thermal dissipater comprises a second material, wherein the first material is identical to the second material.

8. The semiconductor chip package as recited in claim 1, further comprising a heat sink placed directly on the thermal dissipater.

9. A method comprising:
attaching a thermal dissipater to an integrated-circuit die, the thermal dissipater (i) not acting as an integrated circuit and (ii) having a coefficient of thermal expansion similar to that of the integrated-circuit die; and
applying a structural material proximate to the thermal dissipater, the structural material capable of supporting a heat sink in thermal contact with the thermal dissipater.

10. The method as recited in claim 9, wherein applying a structural material comprises:
pouring the structural material onto the integrated-circuit die and the thermal dissipater; and
removing a layer of the structural material effective to expose the thermal dissipater.

11. The method as recited in claim 10, wherein removing the layer comprises using laser ablation to remove the layer.

12. The method as recited in claim 10, wherein removing the layer comprises grinding the layer.

13. The method as recited in claim 9, wherein applying a structural material comprises:
pouring the structural material into a mold containing the integrated-circuit die and the thermal dissipater, the mold designed to (i) leave the thermal dissipater exposed or (ii) leave a thin layer of the structural material residing over the thermal dissipater.

14. The method as recited in claim 9, wherein the structural material is not as thermally conductive as the thermal dissipater.

15. The method as recited in claim 9, wherein:
the integrated-circuit die comprises a first material; and
the thermal dissipater comprises a second material, wherein the first material is identical to the second material.

16. The method as recited in claim 9, wherein:
the integrated-circuit die has a first coefficient of thermal expansion; and
the structural material is a plastic having a second coefficient of thermal expansion dissimilar to the first coefficient of thermal expansion.

17. The method as recited in claim 16, wherein:
the thermal dissipater has a third coefficient of thermal expansion; and
the difference between the third coefficient of thermal expansion and the first coefficient of thermal expansion is less than the difference between the second coefficient of thermal expansion and the first coefficient of thermal expansion.

18. The method as recited in claim 9, wherein attaching the thermal dissipater to the integrated-circuit die includes applying an adhesive film on the thermal dissipater or the integrated-circuit die.

19. The method as recited in claim 9, further comprising:
attaching the integrated-circuit die to a ball grid array;
electrically connecting a solder-ball joint of the ball grid array to a functional circuit within the integrated-circuit die through (i) a via in the ball grid array and (ii) a wire connecting the via to the integrated-circuit die; and
attaching the ball grid array to a printed circuit board.

20. A ball grid array semiconductor chip package comprising:
a ball grid array having (i) an array bottom and (ii) an array top, the array bottom having solder-ball joints for electrically and mechanically connecting the ball grid array semiconductor chip package to a printed circuit board, the array top having a surface-mount contact, one of the solder-ball joints being electrically connected to the surface-mount contact through a via within the ball grid array;
an integrated-circuit die having (i) a die top and (ii) a die bottom, the die bottom being attached to the array top of the ball grid array, the die top having a die contact;
a wire electrically connecting the die contact to the surface-mount contact;
a thermal dissipater attached to the die top, the thermal dissipater (i) not acting as an integrated circuit and (ii) having a coefficient of thermal expansion similar to that of the integrated-circuit die; and
a structural material having a different coefficient of thermal expansion than the integrated-circuit die, wherein the structural material
encapsulates the integrated-circuit die;
encapsulates the wire; and
is in contact with at least part of the thermal dissipater.
